(19) United States
(12) Patent Application Publication
(10) Pub. No.: US 2026/0262374 A1
(43) Pub. Date: Sep. 3, 2026

(54) LIGHT-EMITTING DEVICE DISPLAY PANEL, AND DISPLAY APPARATUS

(71) Applicant: Kunshan Govisionox Optoelectronics Co., Ltd., Kunshan (CN)

(72) Inventors: Rongzhen CUI, Kunshan (CN); Huanhuan ZHANG, Kunshan (CN); Zhimin YAN, Kunshan (CN)

(73) Assignee: Kunshan Govisionox Optoelectronics Co., Ltd., Kunshan (CN)

(21) Appl. No.: 19/654,476

(22) Filed: Apr. 22, 2026

(30) Foreign Application Priority Data
May 16, 2025 (CN) 202510638026.7

(51) Int. Cl. H10K 50/13; H10K 101/10; H10K 101/30; H10K 101/40; H10K 102/00

(52) U.S. Cl. CPC H10K 50/13; H10K 2101/10; H10K 2101/30; H10K 2101/40; H10K 2102/351

(57) ABSTRACT

The light-emitting device includes a first carrier layer, a light-emitting layer, and a second carrier layer sequentially stacked. The first carrier layer is configured to transport holes, and the second carrier layer is configured to transport electrons. The light-emitting layer includes a first sub-light-emitting layer and a second sub-light-emitting layer stacked in a direction from the first carrier layer to the second carrier layer. An excited state energy level of the first sub-light-emitting layer is greater than an excited state energy level of the second sub-light-emitting layer, and a HOMO energy level of the first sub-light-emitting layer is greater than a HOMO energy level of the second sub-light-emitting layer.

### CROSS-REFERENCE TO RELATED APPLICATIONS

The present application claims priority to the Chinese Patent Application 202510638026.7 filed on May 16, 2025, and the entire contents of the aforementioned application are hereby incorporated by reference in its entirety.

### FIELD

The present disclosure relates to the field of touch control technologies, and in particular, to a touch panel and a touch apparatus.

### BACKGROUND

The application Flat-panel display apparatuses based on technologies such as Organic Light Emitting Diodes (OLEDs) and Light Emitting Diodes (LEDs) are widely used in various consumer electronic products such as mobile phones, televisions, notebook computers, and desktop computers due to their advantages of high image quality, low power consumption, thin profile, and wide application range, and have become mainstream in display apparatuses.

However, the performance of current OLED display products needs to be improved.

### SUMMARY

Embodiments of the present application provide a light-emitting device, a display panel, and a display apparatus, aiming to improve the performance of display products.

An embodiment of the present application provides a light-emitting device. The light-emitting device includes a first carrier layer, a light-emitting layer, and a second carrier layer sequentially stacked, and the first carrier layer is configured to transport holes, the second carrier layer is configured to transport electrons, and the light-emitting layer includes a first sub-light-emitting layer and a second sub-light-emitting layer stacked in a direction from the first carrier layer to the second carrier layer, and an excited state energy level of the first sub-light-emitting layer is greater than an excited state energy level of the second sub-light-emitting layer, and a HOMO energy level of the first sub-light-emitting layer is greater than a HOMO energy level of the second sub-light-emitting layer.

An embodiment of the first aspect of the present application further provides a light-emitting device. The light-emitting device includes a first carrier layer, a light-emitting layer, and a second carrier layer sequentially stacked, and the first carrier layer is configured to transport holes, the second carrier layer is configured to transport electrons, and the light-emitting layer includes a first sub-light-emitting layer and a second sub-light-emitting layer stacked in a direction from the first carrier layer to the second carrier layer, and an excited state energy level of the first sub-light-emitting layer is greater than an excited state energy level of the second sub-light-emitting layer, and a LUMO energy level of the first sub-light-emitting layer is lower than a LUMO energy level of the second sub-light-emitting layer.

An embodiment of the present application further provides a light-emitting device. The light-emitting device includes a first carrier layer, a light-emitting layer, and a second carrier layer sequentially stacked, and the first carrier layer is configured to transport holes, the second carrier layer is configured to transport electrons, and the light-emitting layer includes a first sub-light-emitting layer and a second sub-light-emitting layer stacked in a direction from the first carrier layer to the second carrier layer, and an excited state energy level of the first sub-light-emitting layer is less than an excited state energy level of the second sub-light-emitting layer, and a HOMO energy level of the first sub-light-emitting layer is lower than a HOMO energy level of the second sub-light-emitting layer.

An embodiment of the second aspect of the present application further provides a light-emitting device. The light-emitting device includes a first carrier layer, a light-emitting layer, and a second carrier layer sequentially stacked, and the first carrier layer is configured to transport holes, the second carrier layer is configured to transport electrons, and the light-emitting layer includes a first sub-light-emitting layer and a second sub-light-emitting layer stacked in a direction from the first carrier layer to the second carrier layer, and an excited state energy level of the first sub-light-emitting layer is less than an excited state energy level of the second sub-light-emitting layer, and a LUMO energy level of the first sub-light-emitting layer is greater than a LUMO energy level of the second sub-light-emitting layer.

An embodiment of the present application further provides a display panel, including the light-emitting device according to any one of the embodiments.

An embodiment of the present application further provides a display apparatus, including the display panel according to any one of the embodiments.

In the light-emitting device provided by the embodiments of the present application, the light-emitting device includes a first carrier layer, a second carrier layer, and a first sub-light-emitting layer and a second sub-light-emitting layer located between the first carrier layer and the second carrier layer. Both the first sub-light-emitting layer and the second sub-light-emitting layer are used for light emission, the first carrier layer is used for transporting holes, and the second carrier layer is used for transporting electrons. In the first sub-light-emitting layer and the second sub-light-emitting layer, the HOMO energy level of the first sub-light-emitting layer is greater than the HOMO energy level of the second sub-light-emitting layer, making it difficult for holes to transfer from the first sub-light-emitting layer to the second sub-light-emitting layer, allowing more holes to be retained in the first sub-light-emitting layer. Holes and electrons are prone to recombine within the first sub-light-emitting layer to generate triplet excitons. The excited state energy level of the first sub-light-emitting layer is greater than that of the second sub-light-emitting layer, and excitons are easily transferred to the second sub-light-emitting layer and undergo a transition from triplet to singlet states. Therefore, charge recombination and exciton transformation can be isolated from each other, which can improve conversion efficiency and thereby enhance the light-emitting efficiency of the device.

### BRIEF DESCRIPTION OF THE DRAWINGS

Through reading the following detailed description of non-limiting embodiments with reference to the accompanying drawings, other features, purposes, and advantages of the present application will become more apparent. In the drawings, the same or similar reference numerals denote the same or similar features.

FIG. 1 is a schematic structural diagram of a light-emitting device in one embodiment;

FIG. 2 is a schematic diagram of the energy level structure of a light-emitting device in one embodiment;

FIG. 3 is a schematic structural diagram of a light-emitting device provided by an embodiment of the present application;

FIG. 4 is a schematic diagram of the energy level structure of a light-emitting device provided by an embodiment of the first aspect of the present application;

FIG. 5 is a schematic diagram of the energy level structure of a light-emitting device provided by another embodiment of the first aspect of the present application;

FIG. 6 is a schematic diagram of the energy level structure of a light-emitting device provided by yet another embodiment of the first aspect of the present application;

FIG. 7 is a schematic diagram of the energy level structure of a light-emitting device provided by an embodiment of the second aspect of the present application;

FIG. 8 is a schematic diagram of the energy level structure of a light-emitting device provided by another embodiment of the second aspect of the present application;

FIG. 9 is a schematic diagram of the energy level structure of a light-emitting device provided by yet another embodiment of the second aspect of the present application.

### REFERENCE MARK DESCRIPTION

10, first electrode;
20, first carrier layer; 21, hole injection layer; 22, hole transport layer; 23, electron blocking layer;
30, light-emitting layer; 31, first sub-light-emitting layer; 32, second sub-light-emitting layer;
40, second carrier layer; 41, hole blocking layer; 42, electron transport layer; 43, electron injection layer;
50, second electrode.

### DETAILED DESCRIPTION OF THE EMBODIMENTS

The features and exemplary embodiments of various aspects of the present application will be described in detail below. In the following detailed description, numerous specific details are set forth to provide a thorough understanding of the present application. However, it will be apparent in the art that the present application may be practiced without some of these specific details. The description of the embodiments is merely intended to provide a better understanding of the present application by illustrating examples thereof. In the drawings and the following description, at least some well-known structures and techniques are not shown to avoid unnecessarily obscuring the present application; and for clarity, the dimensions of some structures may be exaggerated. Furthermore, the features, structures, or characteristics described below may be combined in any suitable manner in one or more embodiments.

In the description of the present application, it should be noted that unless otherwise specified, “a plurality of” means two or more; terms such as “upper,” “lower,” “left,” “right,” “inner,” “outer,” etc., indicating orientation or positional relationships are only for convenience in describing the present application and simplifying the description, and do not indicate or imply that the referred device or element must have a specific orientation or be constructed and operated in a specific orientation, and thus should not be construed as limiting the present application. In addition, terms such as “first,” “second,” etc., are used only for descriptive purposes and should not be construed as indicating or implying relative importance.

The directional terms appearing in the following description refer to the directions shown in the drawings and are not intended to limit the specific structure of the embodiments of the present application. In the description of the present application, it should also be noted that unless otherwise explicitly specified and defined, the terms “mount,” “connect,” etc., should be interpreted broadly, for example, they may refer to fixed connections, detachable connections, or integral connections; they may refer to direct connections or indirect connections. For those of ordinary skill in the art, the specific meanings of the above terms in the present application can be understood based on the specific context.

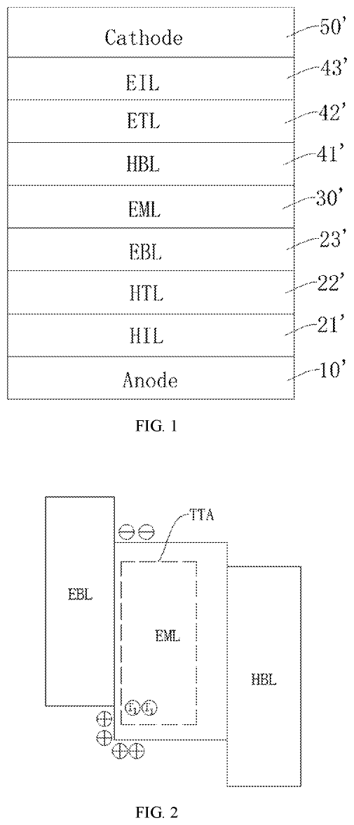

As shown in FIG. 1, it is a schematic structural diagram of a light-emitting device provided by the related art. In this light-emitting device, the device includes an anode 10′, a hole transport layer 22′, an electron blocking layer 23′, a light-emitting layer 30′, a hole blocking layer 41′, an electron transport layer 42′, and a cathode 20′, which are sequentially stacked. The anode 10′ is used to generate holes, and the cathode 20′ is used to generate electrons. As shown in FIG. 2, holes and electrons recombine within the light-emitting layer 30 to form excitons, which include triplet excitons T1. The triplet excitons T1 undergo triplet-triplet annihilation (TTA), causing the triplet excitons T1 to collide and convert into singlet excitons, thereby improving efficiency. However, due to the quenching of some triplet excitons T1 with charges within the light-emitting layer 30′, energy is lost, affecting efficiency. At the same time, the high concentration of triplet excitons in the light-emitting layer 30′ affects the stability of nearby materials, such as the stability of the interface between the electron blocking layer 23′ and the light-emitting layer 30′, leading to issues like degradation of the electron blocking layer 23′.

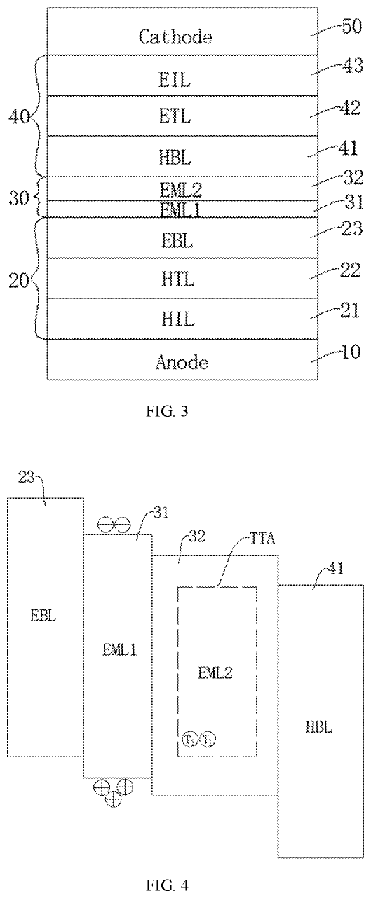

To address the above problems, the present application is proposed. For a better understanding of the present application, the light-emitting device, display panel, and display device provided by the embodiments of the present application will be described in detail below with reference to FIG. 3 and FIG. 4.

Please refer to FIG. 3 and FIG. 4 together. FIG. 3 is a schematic structural diagram of a light-emitting device provided by an embodiment of the present application; FIG. 4 is a schematic diagram of the energy level structure of a light-emitting device provided by an embodiment of the present application.

As shown in FIG. 3 and FIG. 4, an embodiment of the first aspect of the present application provides a light-emitting device. The light-emitting device includes a first carrier layer 20, a light-emitting layer 30, and a second carrier layer 40 sequentially stacked. The first carrier layer 20 is configured to transport holes, and the second carrier layer 40 is configured to transport electrons. The light-emitting layer 30 includes a first sub-light-emitting layer 31 and a second sub-light-emitting layer 32 stacked in a direction from the first carrier layer 20 to the second carrier layer 40. An excited state energy level of the first sub-light-emitting layer 31 is greater than an excited state energy level of the second sub-light-emitting layer 32, and a HOMO energy level of the first sub-light-emitting layer 31 is greater than a HOMO energy level of the second sub-light-emitting layer 32.

In the light-emitting device provided by the embodiment of the present application, the light-emitting device includes the first carrier layer 20, the second carrier layer 40, and the first sub-light-emitting layer 31 and the second sub-light-emitting layer 32 located between the first carrier layer 20 and the second carrier layer 40. Both the first sub-light-emitting layer 31 and the second sub-light-emitting layer 32 are configured to emit light. The first carrier layer 20 is configured to transport holes, and the second carrier layer 40 is configured to transport electrons. In the first sub-light-emitting layer 31 and the second sub-light-emitting layer 32, the HOMO energy level of the first sub-light-emitting layer 31 is greater than the HOMO energy level of the second sub-light-emitting layer 32, making it difficult for holes to transport from the first sub-light-emitting layer 31 to the second sub-light-emitting layer 32. More holes can be retained in the first sub-light-emitting layer 31, so holes and electrons are prone to recombine within the first sub-light-emitting layer 31 to generate triplet excitons T1. The excited state energy level of the first sub-light-emitting layer 31 is greater than the excited state energy level of the second sub-light-emitting layer 32, and the triplet excitons T1 are prone to transfer to the second sub-light-emitting layer 32 and undergo triplet-to-singlet evolution. Therefore, charge recombination and triplet exciton T1 evolution can be isolated from each other, which can improve conversion efficiency and thereby enhance the luminous efficiency of the light-emitting device.

In the embodiment of the present application, as shown in FIG. 4, electrons and holes recombine in the first sub-light-emitting layer 31, while the triplet-to-singlet evolution (TTA) of triplet excitons T1 occurs in the second sub-light-emitting layer 32. Charges and triplet excitons T1 are located in different layer structures, which can increase the distance between charges and triplet excitons T1, mitigate losses due to partial triplet exciton T1 energy and charge quenching, and thereby improve luminous efficiency. In FIG. 4, the region of triplet exciton T1 evolution is schematically indicated by a dashed box.

In one embodiment, the light-emitting device further includes a first electrode 10 and a second electrode 50. The first electrode 10 is located on a side of the first carrier layer 20 away from the light-emitting layer 30, and the second electrode 50 is located on a side of the second carrier layer 40 away from the light-emitting layer 30. The first electrode 10 is, for example, an anode, and the second electrode 50 is, for example, a cathode, and the first electrode 10 can generate holes and the second electrode 50 can generate electrons.

In some embodiments, the mobility of electrons within the light-emitting layer 30 is greater than the mobility of holes within the light-emitting layer 30.

In these embodiments, since the migration rate of electrons is faster and the migration rate of holes is slower, the path length traveled by electrons within the same time period is greater than that traveled by holes. Therefore, within the same time period, electrons are more likely to pass through the second sub-light-emitting layer 32 and move to the first sub-light-emitting layer 31, while holes move to the first sub-light-emitting layer 31. Electrons and holes are more likely to meet and recombine within the first sub-light-emitting layer 31, which is closer to the side of the first carrier layer 20.

In one embodiment, the material of the first sub-light-emitting layer 31 includes a first host material and a light-emitting material, and the material of the second sub-light-emitting layer 32 includes a second host material and a light-emitting material. In one embodiment, the mobility of electrons in the first host material is greater than the mobility of holes in the first host material. The mobility of electrons in the second host material and the mobility of holes in the second host material may be equal, or the mobility of electrons in the second host material may be greater than the mobility of holes in the second host material.

In some embodiments, the HOMO energy level of the first host material is greater than the HOMO energy level of the second host material.

In these embodiments, the proportion of the first host material in the first sub-light-emitting layer 31 is relatively large, and the proportion of the second host material in the second sub-light-emitting layer 32 is relatively large. Therefore, the HOMO energy level of the first host material being greater than the HOMO energy level of the second host material facilitates making the HOMO energy level of the first sub-light-emitting layer 31 greater than the HOMO energy level of the second sub-light-emitting layer 32. In one embodiment, the HOMO energy level H1 of the first host material and the HOMO energy level H2 of the second host material satisfy: 0.1 eV≤H1−H2≤0.6 eV.

In these embodiments, when the HOMO energy level H1 of the first host material and the HOMO energy level H2 of the second host material satisfy the above range, it can mitigate issues caused by the difference between H1 and H2 being too small, which would lead to an excessive amount of holes transferring to the second sub-light-emitting layer 32. It can also mitigate issues caused by the difference between H1 and H2 being too large, which would affect the overall light-emitting performance of the light-emitting layer 30.

In some embodiments, in the first sub-light-emitting layer 31, the mass ratio of the light-emitting material to the first host material is ranged from 1% to 4%. This ensures good carrier transport performance and light-emitting performance.

In some embodiments, the excited state energy level of the first host material is greater than the excited state energy level of the second host material.

In these embodiments, the proportion of the first host material in the first sub-light-emitting layer 31 is relatively large, and the proportion of the second host material in the second sub-light-emitting layer 32 is relatively large. Therefore, the excited state energy level of the first host material being greater than the excited state energy level of the second host material can make the excited state energy level of the first sub-light-emitting layer 31 greater than the excited state energy level of the second sub-light-emitting layer 32.

In some embodiments, in the second sub-light-emitting layer 32, the mass ratio of the light-emitting material to the first host material is ranged from 1% to 4%. This ensures good carrier transport performance and light-emitting performance.

In one embodiment, the light-emitting material is used for emitting blue light. This improves the luminous efficiency of the blue light-emitting device, thereby enhancing the service life of the blue light-emitting unit. When the display panel includes red light-emitting devices, blue light-emitting devices, and green light-emitting devices, this makes the service lives of light-emitting devices of different colors close to each other.

In one embodiment, the triplet excited state energy level ET1 of the first host material is greater than the triplet excited state energy level ET2 of the second host material.

In these embodiments, triplet excitons evolve into singlet excitons, and the light-emitting material utilizes singlet excitons to emit light of the corresponding color. When the triplet excited state energy level ET1 of the first host material is greater than the triplet excited state energy level ET2 of the second host material, it facilitates the transfer of triplet excitons from the first sub-light-emitting layer 31 to the second sub-light-emitting layer 32, making it easier for triplet excitons to evolve into singlet excitons within the second sub-light-emitting layer 32.

In one embodiment, the triplet excited state energy level ET1 of the first host material and the triplet excited state energy level ET2 of the second host material satisfy: 0.1 eV≤ET1−ET2≤0.6 eV.

In these embodiments, the specified energy difference range (0.1 eV≤ET1−ET2≤0.6 eV) can prevent the difference between the triplet excited state energy level ET1 of the first host material and the triplet excited state energy level ET2 of the second host material from being too small, which could lead to residual triplet excitons within the first sub-light-emitting layer 31 and affect luminous efficiency. It also prevents the difference from being too large, which could impact the overall light-emitting effect of the light-emitting layer 30.

In some embodiments, the triplet excited state energy level ET of the light-emitting material is greater than the triplet excited state energy level ET2 of the second host material. The light-emitting material is present in both the first sub-light-emitting layer 31 and the second sub-light-emitting layer 32. When the triplet excited state energy level ET of the light-emitting material is greater than the triplet excited state energy level ET2 of the second host material, it facilitates the evolution of excitons into singlet excitons within the second sub-light-emitting layer 32.

In one embodiment, the triplet excited state energy level ET of the light-emitting material and the triplet excited state energy level ET2 of the second host material satisfy: 0.1 eV≤ET−ET2≤0.6 eV This improves the situation where the difference between the triplet excited state energy level ET of the light-emitting material and the triplet excited state energy level ET2 of the second host material is too small, which could affect the evolution of excitons within the second sub-light-emitting layer 32. It also prevents the difference from being too large, which could impact the overall performance of the light-emitting layer 30.

In some embodiments, the singlet excited state energy level ES2 of the second host material is greater than the singlet excited state energy level ES of the light-emitting material. This ensures that when excitons evolve into singlet excitons, the energy can be more easily transferred to the light-emitting material to achieve the purpose of light emission.

In one embodiment, the singlet excited state energy level ES2 of the second host material and the singlet excited state energy level ES of the light-emitting material satisfy: 0.1 eV≤ES2−ES≤0.6 eV This improves the situation where the difference between the singlet excited state energy level ES2 of the second host material and the singlet excited state energy level ES of the light-emitting material is too small, which could affect energy transfer to the light-emitting material. It also prevents the difference from being too large, which could impact the overall performance of the light-emitting layer 30.

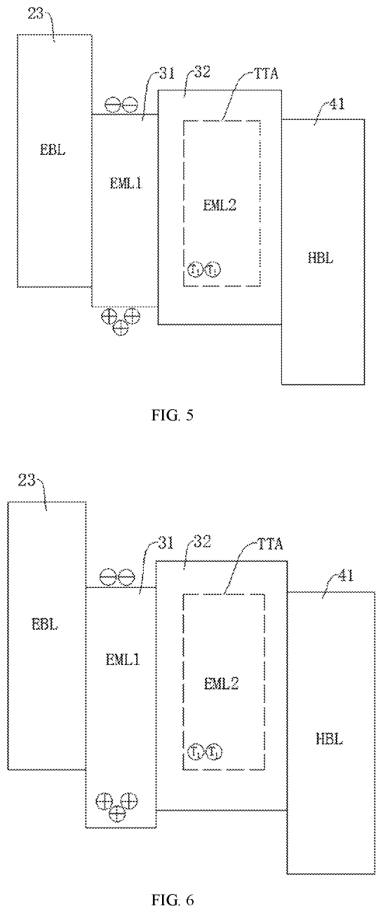

In one embodiment, as shown in FIG. 5 and FIG. 6, the LUMO energy level of the first sub-light-emitting layer 31 may be lower than the LUMO energy level of the second sub-light-emitting layer 32.

In other optional embodiments, the LUMO energy level of the first sub-light-emitting layer 31 is lower than the LUMO energy level of the second sub-light-emitting layer 32. This makes it easier for electrons to transfer from the second sub-light-emitting layer 32 to the first sub-light-emitting layer 31, allowing more electrons to reach the first sub-light-emitting layer 31 to recombine with holes within it to form excitons.

In one embodiment, please refer to the above, the material of the first sub-light-emitting layer 31 includes a first host material and a light-emitting material, the material of the second sub-light-emitting layer 32 includes a second host material and a light-emitting material, and the LUMO energy level of the first host material is lower than the LUMO energy level of the second host material.

In these embodiments, the first host material has a relatively high weight percentage in the first sub-light-emitting layer 31, and the second host material has a relatively high weight percentage in the second sub-light-emitting layer 32. Setting the LUMO energy level of the first host material lower than that of the second host material is conducive to making the LUMO energy level of the first sub-light-emitting layer 31 lower than that of the second sub-light-emitting layer 32.

In one embodiment, the LUMO energy level L1 of the first host material and the LUMO energy level L2 of the second host material satisfy: 0.1 eV≤L2−L1≤0.6 eV This improves the situation where the difference between the LUMO energy level L1 of the first host material and the LUMO energy level L2 of the second host material is too large, which could affect the overall performance of the light-emitting layer 30. It also prevents the difference from being too small, which could hinder the movement of electrons from the second sub-light-emitting layer 32 to the first sub-light-emitting layer 31.

In some embodiments, the thickness of the first sub-light-emitting layer 31 is less than the thickness of the second sub-light-emitting layer 32. The thickness of the first sub-light-emitting layer 31 refers to its extension dimension in the direction from the first carrier layer 20 to the second carrier layer 40. Similarly, the thickness of the second sub-light-emitting layer 32 refers to its extension dimension in the direction from the first carrier layer 20 to the second carrier layer 40.

In these embodiments, the first sub-light-emitting layer 31 has a smaller thickness, and the second sub-light-emitting layer 32 has a larger thickness, allowing excitons to fully evolve within the second sub-light-emitting layer 32.

In one embodiment, the thickness of the light-emitting layer 30 is 20 nm to 27 nm. That is, the sum of the thickness of the first sub-light-emitting layer 31 and the thickness of the second sub-light-emitting layer 32 is 20 nm to 27 nm. This can prevent the luminous efficiency from being affected due to the thickness of the light-emitting layer 30 being too small. It also prevents the situation where the thickness of the light-emitting layer 30 is too large, causing holes and electrons to travel excessively long distances, making it difficult for them to fully recombine and thus affecting luminous efficiency.

In one embodiment, the thickness of the first sub-light-emitting layer 31 is 2 nm to 8 nm. This can both improve the insufficient recombination of holes and electrons due to an excessively small thickness of the first sub-light-emitting layer 31, and also improve the insufficient evolution of excitons due to an excessively large thickness of the first sub-light-emitting layer 31, which would squeeze the space of the second sub-light-emitting layer 32 and affect the light-emitting efficiency.

In one embodiment, the thickness of the second sub-light-emitting layer 32 is 12 nm to 25 nm. This can both improve the insufficient evolution of excitons due to an excessively small thickness of the second sub-light-emitting layer 32, which would affect the light-emitting efficiency, and also improve the insufficient recombination of holes and electrons due to an excessively large thickness of the second sub-light-emitting layer 32, which would squeeze the space of the first sub-light-emitting layer 31.

There are various arrangements for the first carrier layer 20 and the second carrier layer 40. For example, the first carrier layer 20 includes a hole injection layer 21, which can extract holes from the first electrode 10. The first carrier layer 20 may further include a hole transport layer 22, located on a side of the hole injection layer 21 away from the first electrode 10, and holes extracted by the hole injection layer 21 are transported to the light-emitting layer 30 via the hole transport layer 22.

In one embodiment, the first carrier layer 20 may further include an electron blocking layer 23, located between the hole transport layer 22 and the first sub-light-emitting layer 31. The electron blocking layer 23 is used to block electrons overflowing from the first sub-light-emitting layer 31 toward the hole transport layer 22, thereby improving the situation where electrons and holes meet and recombine on the side of the hole transport layer 22, and enhancing the light-emitting efficiency.

The contact interface between the electron blocking layer 23 and the light-emitting layer 30 is a sensitive interface. The exciton evolution process releases a large amount of energy, and high energy may damage this sensitive interface. In the embodiments of the present application, the light-emitting layer 30 is divided into the first sub-light-emitting layer 31 and the second sub-light-emitting layer 32. The first sub-light-emitting layer 31 is a charge recombination layer, meaning holes and electrons recombine into excitons within the first sub-light-emitting layer 31, and the excitons are transferred to the second sub-light-emitting layer 32 for evolution. Therefore, the distance between exciton evolution and the sensitive interface is relatively far, which can effectively mitigate damage to the sensitive interface caused by exciton evolution, thereby improving the service life of the light-emitting device.

In one embodiment, the second carrier layer 40 includes an electron injection layer 43, which is used to extract electrons from the second electrode 50. In one embodiment, the second carrier layer 40 further includes an electron transport layer 42, located on a side of the electron injection layer 43 away from the second electrode 50, and electrons extracted by the electron injection layer 43 can be transferred to the light-emitting layer 30 via the electron transport layer 42.

In one embodiment, the second carrier layer 40 further includes a hole blocking layer 41, located between the second sub-light-emitting layer 32 and the electron transport layer 42. The hole blocking layer 41 is used to block holes overflowing from the light-emitting layer 30 toward the electron transport layer 42, thereby improving the situation where holes meet and recombine with electrons within the electron transport layer 42, and enhancing the light-emitting efficiency.

In one embodiment, the thickness of the hole transport layer 22 is greater than the thickness of the electron transport layer 42.

In these embodiments, the hole transport layer 22 has a larger thickness, resulting in a longer transport time for holes within the hole transport layer 22. The electron transport layer 42 has a smaller thickness, resulting in a shorter transport time for electrons within the electron transport layer 42. Electrons can enter the light-emitting layer 30 before holes. When the electrons continue to move to the first sub-light-emitting layer 31, the holes also move to the first sub-light-emitting layer 31, allowing more electrons and holes to meet and recombine within the first sub-light-emitting layer 31.

In one embodiment, in other embodiments, the mobility of holes in the hole transport layer 22 is less than the mobility of electrons in the electron transport layer 42. In these embodiments, the thickness of the hole transport layer 22 and the thickness of the electron transport layer 42 may be equal. Moreover, by adjusting the mobility of holes in the hole transport layer 22 and the mobility of electrons in the electron transport layer 42, the thickness of the hole transport layer 22 may be less than the thickness of the electron transport layer 42, while still allowing holes and electrons to meet within the first sub-light-emitting layer 31.

To further illustrate the beneficial effects of the solution of the present application, comparative experiments were conducted. An Example 1 and a Comparative Example 1 of a light-emitting device for emitting blue light are provided. The light-emitting device of Example 1 includes, sequentially stacked, a first electrode 10, a hole injection layer 21, a hole transport layer 22, an electron blocking layer 23, a first sub-light-emitting layer 31, a second sub-light-emitting layer 32, a hole blocking layer 41, an electron transport layer 42, an electron injection layer 43, and a second electrode 50. The light-emitting device of Comparative Example 1 includes, sequentially stacked, a first electrode 10, a hole injection layer 21, a hole transport layer 22, an electron blocking layer 23, a single-layer light-emitting layer 30, a hole blocking layer 41, an electron transport layer 42, an electron injection layer 43, and a second electrode 50. The total thickness of the first sub-light-emitting layer 31 and the second sub-light-emitting layer 32 in Example 1 is the same as the thickness of the single-layer light-emitting layer 30 in Comparative Example 1. The material of the second sub-light-emitting layer 32 in Example 1 is the same as the material of the single-layer light-emitting layer 30 in Comparative Example 1. The difference lies in that the first sub-light-emitting layer 31 is provided in Example 1, and the triplet excited state energy level ET1 of the first host material of the first sub-light-emitting layer 31 and the triplet excited state energy level ET2 of the second host material of the second sub-light-emitting layer 32 satisfy: ET1−ET2=0.3 eV. By measuring the driving voltage, light-emitting efficiency, and lifetime of Example 1 and Comparative Example 1, the following table is obtained:

| | Driving Voltage | Efficiency | Lifetime |
|---|---|---|---|
| Example 1 | 99.7% | 104.8% | 211% |
| Comparative Example | 100% | 100% | 100% |
| 1 | | | |

As can be seen from the above table, by adding the first sub-light-emitting layer 31, without changing the overall thickness of the light-emitting layer 30, the driving voltage of the light-emitting device decreases by 0.3%, the efficiency increases by 4.8%, and the lifetime increases by 111%. Therefore, by providing the two-layer structure of the first sub-light-emitting layer 31 and the second sub-light-emitting layer 32, allowing holes and electrons to recombine within the first sub-light-emitting layer 31 and exciton evolution to occur within the second sub-light-emitting layer 32, charge recombination and exciton evolution are isolated from each other, which can effectively improve the efficiency and service life of the light-emitting device.

Furthermore, an embodiment 2 of a light-emitting device for emitting blue light and a comparative example 2 are also provided. The light-emitting device of embodiment 2 includes a first electrode 10, a hole injection layer 21, a hole transport layer 22, an electron blocking layer 23, a first sub-light-emitting layer 31, a second sub-light-emitting layer 32, a hole blocking layer 41, an electron transport layer 42, an electron injection layer 43, and a second electrode 50, which are sequentially stacked. The light-emitting device of comparative example 2 includes a first electrode 10, a hole injection layer 21, a hole transport layer 22, an electron blocking layer 23, a single light-emitting layer 30, a hole blocking layer 41, an electron transport layer 42, an electron injection layer 43, and a second electrode 50, which are sequentially stacked. The total thickness of the first sub-light-emitting layer 31 and the second sub-light-emitting layer 32 in embodiment 2 is the same as the thickness of the single light-emitting layer 30 in comparative example 2. The material of the second sub-light-emitting layer 32 in embodiment 2 is the same as the material of the single light-emitting layer 30 in comparative example 2. The difference lies in that a first sub-light-emitting layer 33 is provided in comparative example 2, and the triplet excited state energy level ET1 of the first host material of the first sub-light-emitting layer 33 and the triplet excited state energy level ET2 of the second host material of the second sub-light-emitting layer 32 satisfy: ET1−ET2=0.2 eV. By measuring the driving voltage, luminous efficiency, and lifetime of embodiment 2 and comparative example 2, the following table is obtained:

| | Driving Voltage | Efficiency | Lifetime |
|---|---|---|---|
| Embodiment 2 | 89.9% | 106.8% | 150% |
| Comparative | 100% | 100% | 100% |
| Example 2 | | | |

As can be seen from the above table, by adding the first sub-light-emitting layer 31, without changing the overall thickness of the light-emitting layer 30, the driving voltage of the light-emitting device decreases by 10.1%, the efficiency increases by 6.8%, and the lifetime increases by 50%. Therefore, by providing the two light-emitting layer 30 structures of the first sub-light-emitting layer 31 and the second sub-light-emitting layer 32, holes and electrons recombine within the first sub-light-emitting layer 31, and exciton evolution occurs within the second sub-light-emitting layer 32. The charge recombination and exciton evolution are isolated from each other, which can effectively improve the efficiency and service life of the light-emitting device.

As shown in FIG. 6, an embodiment of the first aspect of the present application further provides a light-emitting device. The light-emitting device includes a first carrier layer 20, a light-emitting layer 30, and a second carrier layer 40, which are sequentially stacked. The first carrier layer 20 is configured to transport holes, and the second carrier layer 40 is configured to transport electrons. The light-emitting layer 30 includes a first sub-light-emitting layer 31 and a second sub-light-emitting layer 32, which are stacked in a direction from the first carrier layer 20 to the second carrier layer 40. The excited state energy level of the first sub-light-emitting layer 31 is greater than the excited state energy level of the second sub-light-emitting layer 32, and the LUMO energy level of the first sub-light-emitting layer 31 is lower than the LUMO energy level of the second sub-light-emitting layer 32.

In the light-emitting device provided by the embodiment of the present application, the light-emitting device includes a first carrier layer 20, a second carrier layer 40, and a first sub-light-emitting layer 31 and a second sub-light-emitting layer 32 located between the first carrier layer 20 and the second carrier layer 40. Both the first sub-light-emitting layer 31 and the second sub-light-emitting layer 32 are configured to emit light. The first carrier layer 20 is configured to transport holes, and the second carrier layer 40 is configured to transport electrons. In the first sub-light-emitting layer 31 and the second sub-light-emitting layer 32, the LUMO energy level of the first sub-light-emitting layer 31 is lower than the LUMO energy level of the second sub-light-emitting layer 32, making it easier for electrons to move from the second sub-light-emitting layer 32 to the first sub-light-emitting layer 31. More electrons can move to the first sub-light-emitting layer 31, and holes and electrons easily recombine within the first sub-light-emitting layer 31 to generate triplet excitons. The excited state energy level of the first sub-light-emitting layer 31 is greater than the excited state energy level of the second sub-light-emitting layer 32, and excitons easily transfer to the second sub-light-emitting layer 32 and undergo triplet-to-singlet evolution. Therefore, charge recombination and exciton evolution can be isolated from each other, which can improve conversion efficiency and thereby enhance the luminous efficiency of the light-emitting device.

Please refer to

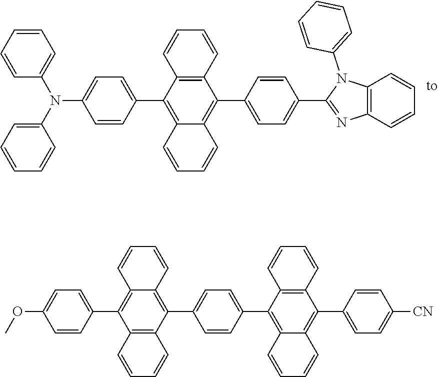 [SMILES: c1ccc(N(c2ccccc2)c2ccc(-c3c4ccccc4c(-c4ccc(-c5nc6ccccc6n5-c5ccccc5)cc4)c4ccccc34)cc2)cc1 ; COc1ccc(-c2c3ccccc3c(-c3ccc(-c4c5ccccc5c(-c5ccc(C#N)cc5)c5ccccc45)cc3)c3ccccc23)cc1]

together. The light-emitting device of the embodiment of the present application and the light-emitting device of any of the above-mentioned embodiments can be cross-referenced. For example, in the light-emitting device of the embodiment of the present application, the material of the first sub-light-emitting layer 31 includes the aforementioned first host material and light-emitting material, the material of the second sub-light-emitting layer 32 includes the aforementioned second host material and light-emitting material, and the LUMO energy level of the first host material is lower than the LUMO energy level of the second host material, etc.

As shown in

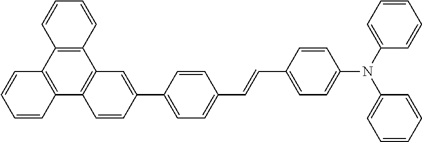 [SMILES: C(=C\c1ccc(N(c2ccccc2)c2ccccc2)cc1)/c1ccc(-c2ccc3c4ccccc4c4ccccc4c3c2)cc1]

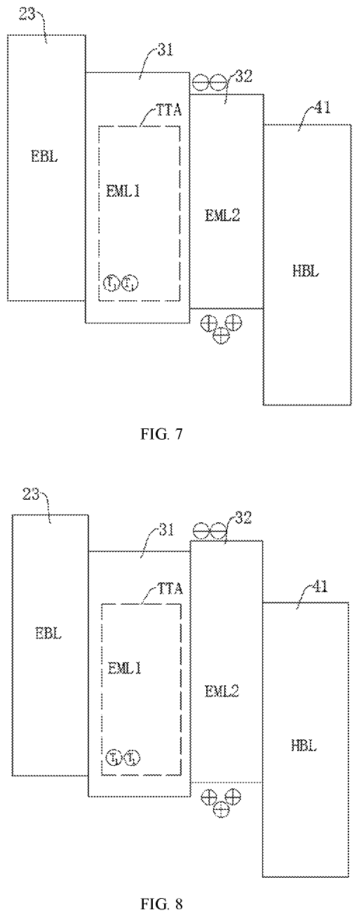

and FIG. 7, an embodiment of the second aspect of the present application further provides a light-emitting device. The light-emitting device includes a first carrier layer 20, a light-emitting layer 30, and a second carrier layer 40, which are sequentially stacked. The first carrier layer 20 is configured to transport holes, and the second carrier layer 40 is configured to transport electrons. The light-emitting layer 30 includes a first sub-light-emitting layer 31 and a second sub-light-emitting layer 32, which are stacked in a direction from the first carrier layer 20 to the second carrier layer 40. The excited state energy level of the first sub-light-emitting layer 31 is less than the excited state energy level of the second sub-light-emitting layer 32, and the HOMO energy level of the first sub-light-emitting layer 31 is lower than the HOMO energy level of the second sub-light-emitting layer 32.

In the light-emitting device provided by the embodiment of the present application, the light-emitting device includes a first carrier layer 20, a second carrier layer 40, and a first sub-light-emitting layer 31 and a second sub-light-emitting layer 32 located between the first carrier layer 20 and the second carrier layer 40. Both the first sub-light-emitting layer 31 and the second sub-light-emitting layer 32 are configured to emit light. The first carrier layer 20 is configured to transport holes, and the second carrier layer 40 is configured to transport electrons. In the first sub-light-emitting layer 31 and the second sub-light-emitting layer 32, the HOMO energy level of the first sub-light-emitting layer 31 is lower than the HOMO energy level of the second sub-light-emitting layer 32, making it easier for holes to move from the first sub-light-emitting layer 31 to the second sub-light-emitting layer 32. More holes can move to the second sub-light-emitting layer 32, and holes and electrons easily recombine within the second sub-light-emitting layer 32 to generate triplet excitons. The excited state energy level of the first sub-light-emitting layer 31 is lower than the excited state energy level of the second sub-light-emitting layer 32, and excitons easily transfer to the first sub-light-emitting layer 31 and undergo triplet-to-singlet evolution. Therefore, charge recombination and exciton evolution can be isolated from each other, which can improve conversion efficiency and thereby enhance the luminous efficiency of the light-emitting device.

The light-emitting device provided by the embodiment of the second aspect of the present application differs from the light-emitting device provided by the embodiment of the first aspect described above in that, in the light-emitting device provided by the embodiment of the first aspect, the first sub-light-emitting layer 31 is a recombination layer where holes and electrons combine to form excitons, and the second sub-light-emitting layer 32 is a conversion layer where excitons convert and transfer energy to the light-emitting material. Conversely, in the light-emitting device provided by the embodiment of the second aspect, the first sub-light-emitting layer 31 is the conversion layer where excitons convert and transfer energy to the light-emitting material, and the second sub-light-emitting layer 32 is the recombination layer where holes and electrons combine to form excitons. Therefore, in the light-emitting device provided by the embodiment of the second aspect of the present application, the comparison between the HOMO energy level of the first sub-light-emitting layer 31 and the HOMO energy level of the second sub-light-emitting layer 32 is opposite to that in the light-emitting device provided by the embodiment of the first aspect. Similarly, the comparison between the excited state energy level of the first sub-light-emitting layer 31 and the excited state energy level of the second sub-light-emitting layer 32 is also opposite to that in the light-emitting device provided by the embodiment of the first aspect. Furthermore, to further ensure that holes and electrons recombine within the second sub-light-emitting layer 32 and excitons convert within the first sub-light-emitting layer 31, the relevant properties of the first sub-light-emitting layer 31 and the second sub-light-emitting layer 32 provided by the embodiment of the second aspect are opposite to those of the first sub-light-emitting layer 31 and the second sub-light-emitting layer 32 provided by the embodiment of the first aspect.

For example, in some embodiments, the mobility of electrons within the light-emitting layer 30 is less than the mobility of holes within the light-emitting layer 30. This facilitates the movement of holes and electrons to the second sub-light-emitting layer 32.

In some embodiments, the material of the first sub-light-emitting layer 31 includes a first host material and a light-emitting material, and the material of the second sub-light-emitting layer 32 includes a second host material and a light-emitting material. The HOMO energy level of the first host material is lower than the HOMO energy level of the second host material, which is beneficial for making the HOMO energy level of the first sub-light-emitting layer 31 lower than the HOMO energy level of the second sub-light-emitting layer 32.

In one embodiment, the HOMO energy level H1 of the first host material and the HOMO energy level H2 of the second host material satisfy: 0.1 eV≤H2−H1≤0.6 eV. This improves the situation where the difference between the HOMO energy level H1 of the first host material and the HOMO energy level H2 of the second host material is too small, which makes it difficult for holes to accumulate more in the second sub-light-emitting layer 32; it also improves the situation where the difference between the HOMO energy level H1 of the first host material and the HOMO energy level H2 of the second host material is too large, which affects the overall device performance of the light-emitting layer 30.

In one embodiment, the excited state energy level of the first host material is less than the excited state energy level of the second host material. This is beneficial for making the excited state energy level of the first sub-light-emitting layer 31 less than the excited state energy level of the second sub-light-emitting layer 32.

In one embodiment, the light-emitting material is used for emitting blue light. This can improve the performance of blue light-emitting devices.

In one embodiment, the triplet excited state energy level ET1 of the first host material is less than the triplet excited state energy level ET2 of the second host material. This makes it easier for excitons to move to the first sub-light-emitting layer 31.

In one embodiment, the triplet excited state energy level ET1 of the first host material and the triplet excited state energy level ET2 of the second host material satisfy: 0.1 eV≤ET2≤ET1≤0.6 eV. This improves the situation where the difference between the triplet excited state energy level ET1 of the first host material and the triplet excited state energy level ET2 of the second host material is too small, which affects the movement of excitons to the first sub-light-emitting layer 31; it also improves the situation where the difference between the triplet excited state energy level ET1 of the first host material and the triplet excited state energy level ET2 of the second host material is too large, which affects the overall performance of the light-emitting layer 30.

In one embodiment, the triplet excited state energy level ET of the light-emitting material is less than the triplet excited state energy level ET2 of the second host material. This is beneficial for the movement of excitons to the first sub-light-emitting layer 31.

In one embodiment, the triplet excited state energy level ET of the light-emitting material and the triplet excited state energy level ET2 of the second host material satisfy: 0.1 eV≤ET2−ET≤0.6 eV This improves the situation where the difference between the triplet excited state energy level ET of the light-emitting material and the triplet excited state energy level ET2 of the second host material is too small, which affects the movement of excitons to the first sub-light-emitting layer 31; it also improves the situation where the difference between the triplet excited state energy level ET of the light-emitting material and the triplet excited state energy level ET2 of the second host material is too large, which affects the overall performance of the light-emitting layer 30.

In one embodiment, the singlet excited state energy level ES2 of the second host material is less than the singlet excited state energy level ES of the light-emitting material. This allows energy to be transferred to the light-emitting material during exciton conversion, improving the light-emitting effect.

In one embodiment, the singlet excited state energy level ES2 of the second host material and the singlet excited state energy level ES of the light-emitting material satisfy: 0.1 eV≤ES−ES2≤0.6 eV This improves the situation where the difference between the singlet excited state energy level ES2 of the second host material and the singlet excited state energy level ES of the light-emitting material is too small, which affects the transfer of exciton energy to the light-emitting material; it also improves the situation where the difference between the singlet excited state energy level ES2 of the second host material and the singlet excited state energy level ES of the light-emitting material is too large, which affects the overall performance of the light-emitting layer 30.

In some embodiments, as shown in <FIG. 8>, the LUMO energy level of the first sub-light-emitting layer 31 is less than the LUMO energy level of the second sub-light-emitting layer 32.

In one embodiment, as shown in <FIG. 7>, the LUMO energy level of the first sub-light-emitting layer 31 is greater than the LUMO energy level of the second sub-light-emitting layer 32. This makes it difficult for electrons to move from the second sub-light-emitting layer 32 to the first sub-light-emitting layer 31, causing more electrons to remain within the second sub-light-emitting layer 32 to recombine with holes and form excitons.

In one embodiment, the LUMO energy level L1 of the first host material and the LUMO energy level L2 of the second host material satisfy: 0.1 eV≤L1−L2≤0.6 eV. This improves the situation where the difference between the LUMO energy level L2 of the second host material and the LUMO energy level L1 of the first host material is too large, which affects the overall performance of the light-emitting layer 30; it also improves the situation where the difference between the LUMO energy level L2 of the second host material and the LUMO energy level L1 of the first host material is too small, which affects the movement of electrons.

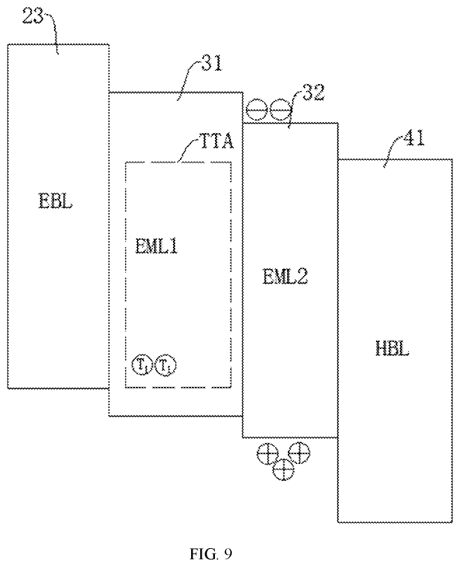

As shown in FIG. 1 and FIG. 9, an embodiment of the second aspect of the present application further provides a light-emitting device. The light-emitting device includes a first carrier layer 20, a light-emitting layer 30, and a second carrier layer 40 sequentially stacked. The first carrier layer 20 is configured to transport holes, and the second carrier layer 40 is configured to transport electrons. The light-emitting layer 30 includes a first sub-light-emitting layer 31 and a second sub-light-emitting layer 32 stacked in a direction from the first carrier layer 20 to the second carrier layer 40. The excited state energy level of the first sub-light-emitting layer 31 is lower than the excited state energy level of the second sub-light-emitting layer 32, and the LUMO energy level of the first sub-light-emitting layer 31 is higher than the LUMO energy level of the second sub-light-emitting layer 32.

In the light-emitting device provided by the embodiment of the present application, the light-emitting device includes the first carrier layer 20, the second carrier layer 40, and the first sub-light-emitting layer 31 and the second sub-light-emitting layer 32 located between the first carrier layer 20 and the second carrier layer 40. Both the first sub-light-emitting layer 31 and the second sub-light-emitting layer 32 are configured to emit light. The first carrier layer 20 is configured to transport holes, and the second carrier layer 40 is configured to transport electrons. In the first sub-light-emitting layer 31 and the second sub-light-emitting layer 32, the LUMO energy level of the first sub-light-emitting layer 31 is higher than the LUMO energy level of the second sub-light-emitting layer 32, making it difficult for electrons to move from the second sub-light-emitting layer 32 to the first sub-light-emitting layer 31. More electrons can remain in the second sub-light-emitting layer 32, where holes and electrons are prone to recombine to generate triplet excitons. The excited state energy level of the first sub-light-emitting layer 31 is lower than the excited state energy level of the second sub-light-emitting layer 32, and excitons are prone to transfer to the first sub-light-emitting layer 31 and undergo triplet-to-singlet evolution. Therefore, charge recombination and exciton evolution can be isolated from each other, which can improve the conversion efficiency and thereby enhance the light-emitting efficiency of the light-emitting device.

As shown in FIG. 1, FIG. 7 to FIG. 9, the light-emitting device of the embodiment of the present application and the light-emitting device provided by any of the aforementioned second aspect embodiments can be cross-referenced. For example, in the light-emitting device provided by the embodiment of the present application, the material of the first sub-light-emitting layer 31 includes a first host material and a light-emitting material, and the material of the second sub-light-emitting layer 32 includes a second host material and a light-emitting material. The LUMO energy level of the first host material is higher than the LUMO energy level of the second host material, and so on.

In the light-emitting device provided by the second aspect embodiment, in one embodiment, the thickness of the first sub-light-emitting layer 31 is greater than the thickness of the second sub-light-emitting layer 32. In these embodiments, the first sub-light-emitting layer 31 has a larger thickness, and the second sub-light-emitting layer 32 has a smaller thickness, allowing excitons to fully evolve in the first sub-light-emitting layer 31.

In the light-emitting device provided by the second aspect embodiment, in one embodiment, the thickness of the light-emitting layer 30 is 20 nm to 27 nm. That is, the sum of the thickness of the first sub-light-emitting layer 31 and the thickness of the second sub-light-emitting layer 32 is 20 nm to 27 nm. This can both improve the light-emitting efficiency affected by an excessively small thickness of the light-emitting layer 30 and mitigate the issue where an excessively large thickness of the light-emitting layer 30 leads to overly long movement distances for holes and electrons, making full recombination difficult and affecting light-emitting efficiency.

In the light-emitting device provided by the second aspect embodiment, in one embodiment, the thickness of the second sub-light-emitting layer 32 is 2 nm to 8 nm. This can both improve the situation where an excessively small thickness of the second sub-light-emitting layer 32 prevents sufficient recombination of holes and electrons, and mitigate the issue where an excessively large thickness of the second sub-light-emitting layer 32 compresses the space of the first sub-light-emitting layer 31, preventing excitons from fully evolving and affecting light-emitting efficiency.

In the light-emitting device provided by the second aspect embodiment, in one embodiment, the thickness of the first sub-light-emitting layer 31 is 12 nm to 25 nm. This can both improve the situation where an excessively small thickness of the first sub-light-emitting layer 31 prevents excitons from fully evolving, affecting light-emitting efficiency, and mitigate the issue where an excessively large thickness of the first sub-light-emitting layer 31 compresses the space of the second sub-light-emitting layer 32, preventing sufficient recombination of holes and electrons.

In the light-emitting device provided by the second aspect embodiment, the configuration of the first carrier layer 20 and the second carrier layer 40 can refer to the light-emitting device provided by the aforementioned first aspect embodiment. For example, the first carrier layer 20 includes at least one of a hole injection layer 21, a hole transport layer 22, and an electron blocking layer 23. In one embodiment, the second carrier layer 40 includes at least one of an electron injection layer 43, an electron transport layer 42, and a hole blocking layer 41.

In the light-emitting device provided by the second aspect embodiment, in one embodiment, the thickness of the hole transport layer 22 is less than the thickness of the electron transport layer 42.

In these embodiments, the hole transport layer 22 has a smaller thickness, resulting in a shorter transport time for holes within the hole transport layer 22. The electron transport layer 42 has a larger thickness, resulting in a longer transport time for electrons within the electron transport layer 42. Holes can enter the light-emitting layer 30 before electrons. When holes continue to move to the second sub-light-emitting layer 32, electrons also move to the second sub-light-emitting layer 32, allowing more electrons and holes to meet and recombine in the second sub-light-emitting layer 32.

In the light-emitting device provided by the second aspect embodiment, in one embodiment, in other embodiments, the mobility of holes in the hole transport layer 22 is greater than the mobility of electrons in the electron transport layer 42. In these embodiments, the thickness of the hole transport layer 22 and the thickness of the electron transport layer 42 may be equal. Moreover, by adjusting the mobility of holes in the hole transport layer 22 and the mobility of electrons in the electron transport layer 42, the thickness of the hole transport layer 22 may even be greater than the thickness of the electron transport layer 42, while still allowing holes and electrons to meet within the second sub-light-emitting layer 32.

In any of the above embodiments, the light-emitting material may include a fluorescent material, enabling the light-emitting layer 30 to emit light of different colors.

In one embodiment, the light-emitting material includes one of the following four categories:
First category: fluorescent materials;
Second category: multiple resonance materials;
Third category: boron-nitrogen-based materials;
Fourth category: non-boron-nitrogen-based boron-oxygen or boron-sulfur materials.

In these embodiments, the selection range for light-emitting materials is broader. Users can choose light-emitting materials with high yield and good lifespan according to actual usage requirements, thereby reducing the manufacturing cost of the display panel and improving its service life.

In one embodiment, the multiple resonance material includes a multiple resonance material in which the nitrogen atoms on both sides of the boron-nitrogen bond are not involved in ring formation. In one embodiment, the fluorescent material includes fluorescent materials based on perylene, phenanthrene, fluorene, anthracene, and pyrene. In one embodiment, the boron-nitrogen material includes boron-nitrogen materials in which the nitrogen atoms on both sides are involved in ring formation, polycyclic boron-nitrogen rings, and boron-nitrogen materials with polycyclic boron-nitrogen rings at different positions, to enrich the variety of light-emitting materials. In one embodiment, the light-emitting material includes at least one of the following materials:

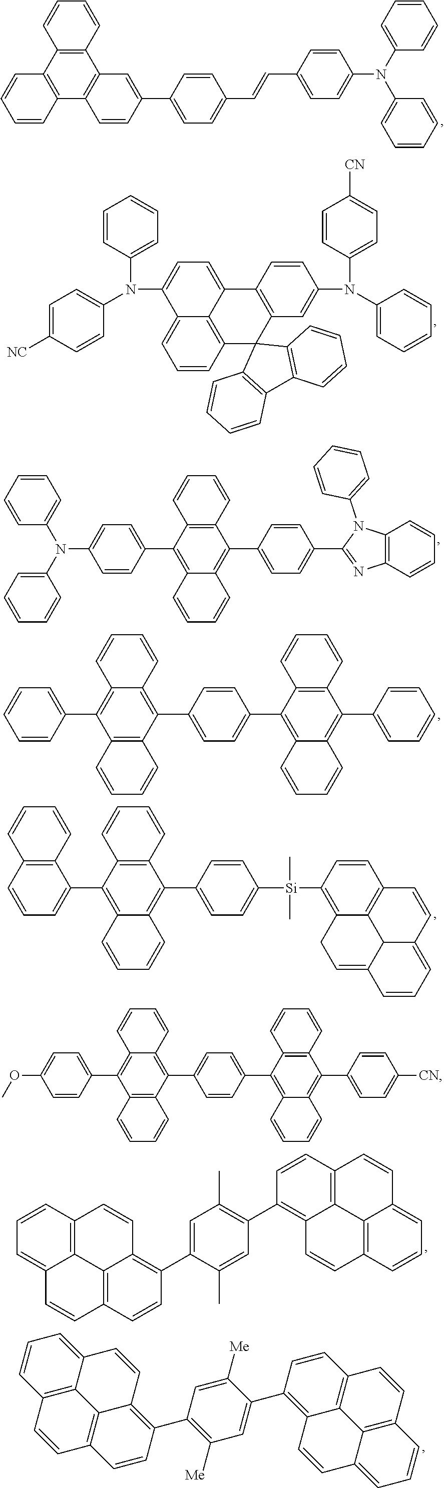

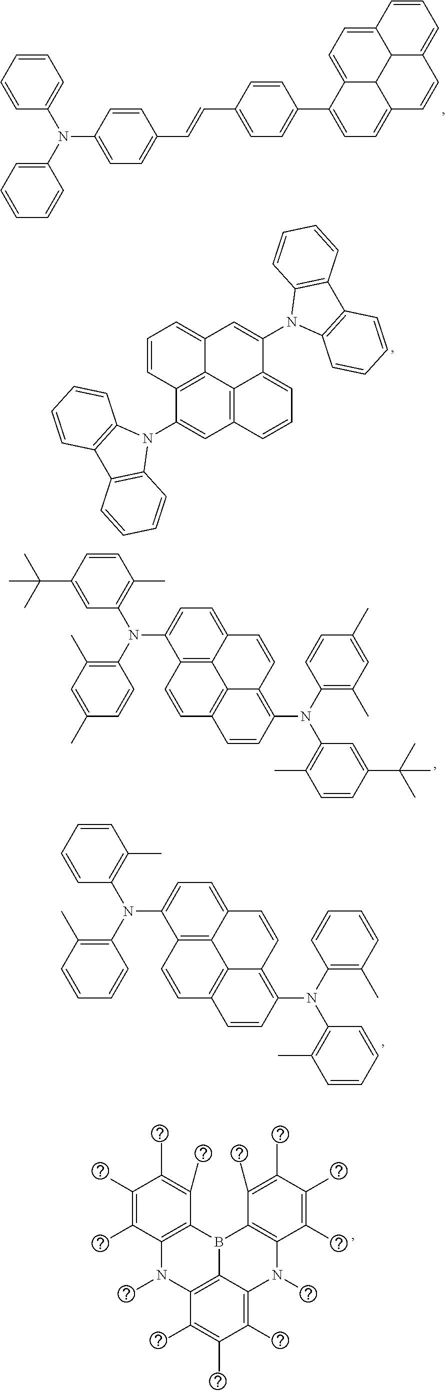

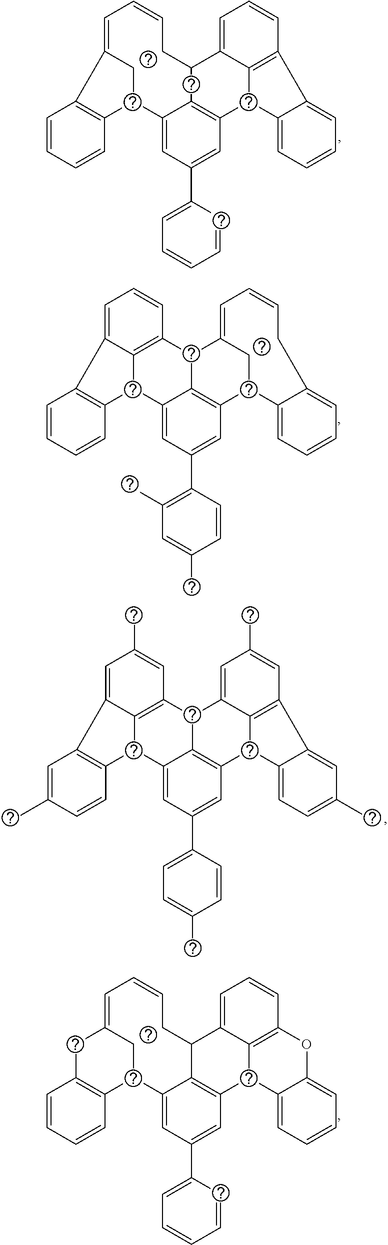

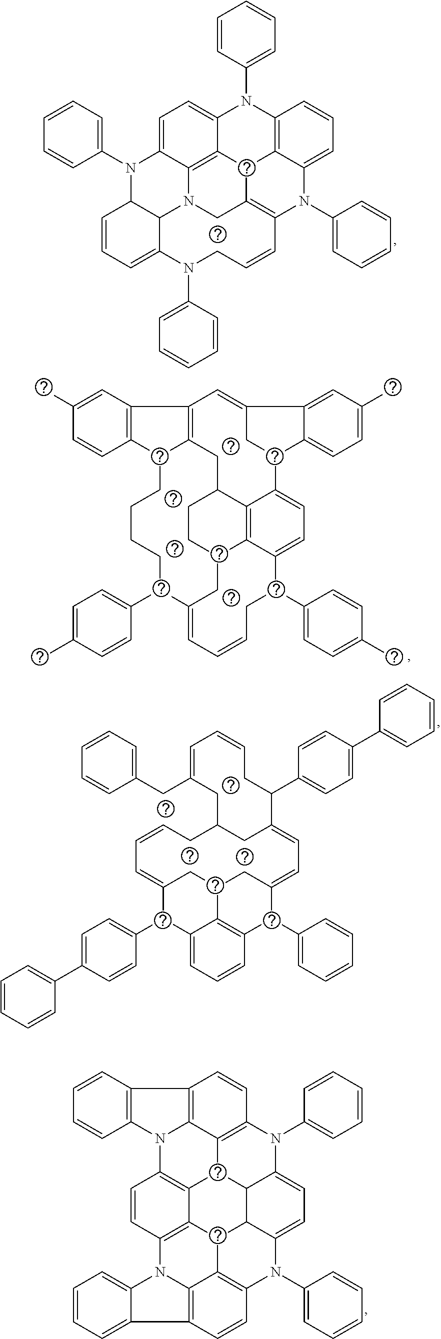

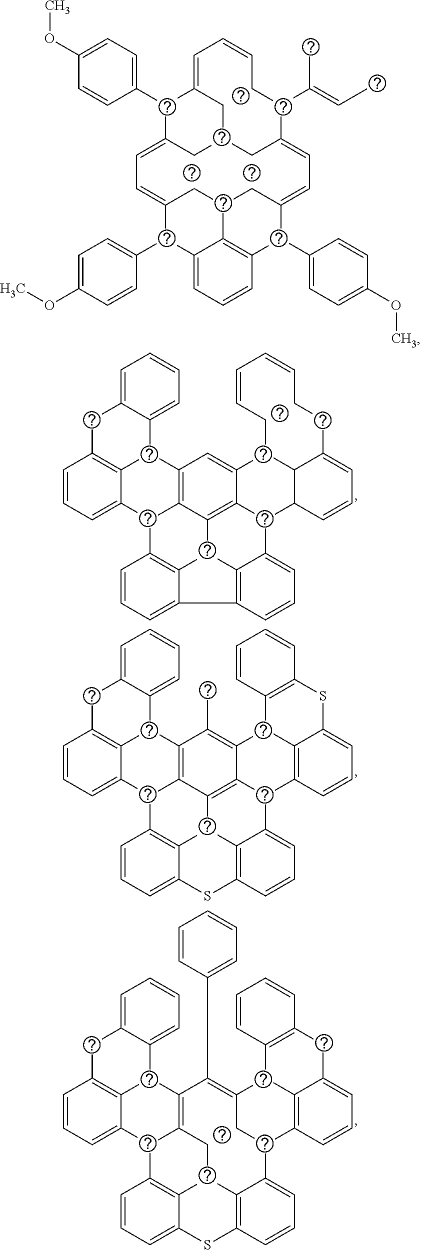

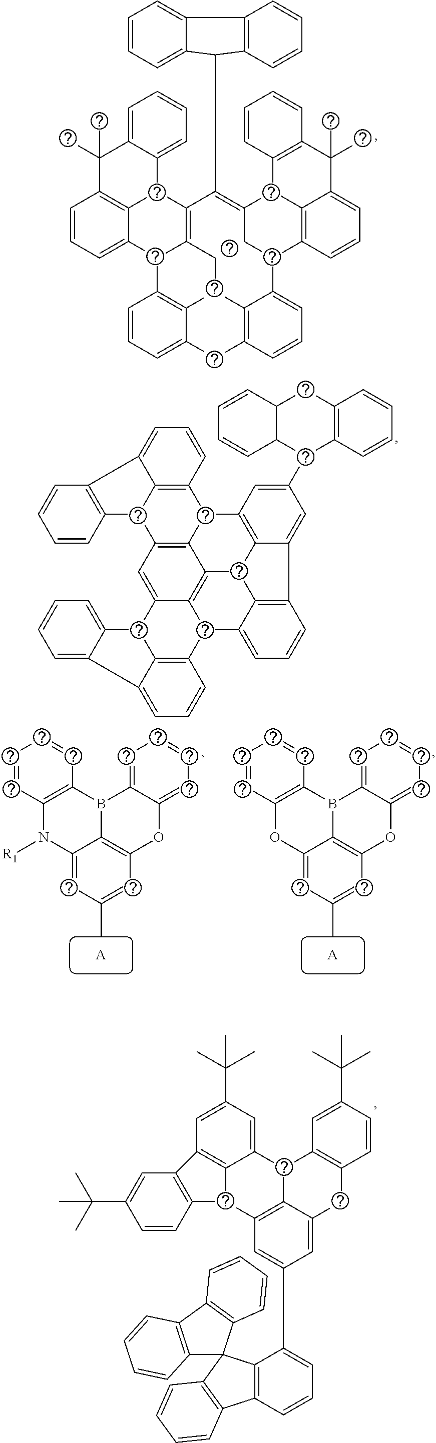

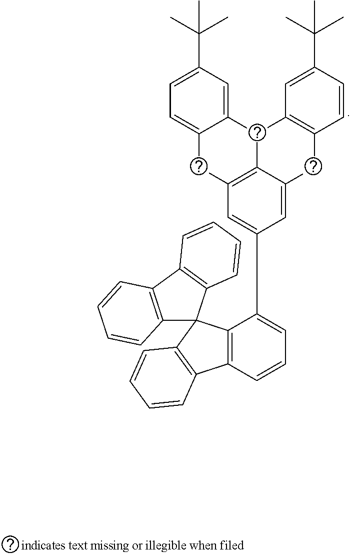 [SMILES: CC(C)(C)c1ccc2c(c1)C1c3cc(C(C)(C)C)ccc3Cc3cc(-c4cccc5c4C4(c6ccccc6-c6ccccc64)c4ccccc4-5)cc(c31)C2]

In one embodiment, the first host material and the second host material may be selected from anthracene-based compounds, for example.

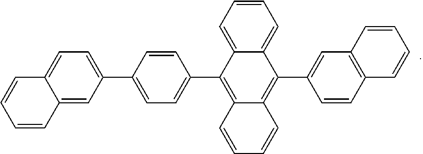 [SMILES: c1ccc2cc(-c3ccc(-c4c5ccccc5c(-c5ccc6ccccc6c5)c5ccccc45)cc3)ccc2c1]

Embodiments of the present application further provide a display panel, including the light-emitting device according to any embodiment of the first aspect described above or the light-emitting device provided by any embodiment of the second aspect. Since the display panel provided by the embodiments of the present application includes the light-emitting device according to any embodiment of the first aspect described above or the light-emitting device provided by any embodiment of the second aspect, the display panel provided by the embodiments of the present application has the beneficial effects of the light-emitting device according to any embodiment of the first aspect or the light-emitting device provided by any embodiment of the second aspect, which will not be repeated here. Embodiments of the present application further provide a display device, including the display panel according to any embodiment of the third aspect described above. Since the display device provided by the embodiments of the present application includes the display panel according to any embodiment of the third aspect described above, the display device provided by the embodiments of the present application has the beneficial effects of the display panel according to any embodiment of the third aspect, which will not be repeated here. The display device in the embodiments of the present application includes, but is not limited to, devices with display functions such as mobile phones, personal digital assistants (PDAs), tablet computers, e-books, televisions, access control systems, smart landline phones, and consoles. Although the present application has been described with reference to preferred embodiments, various modifications can be made and components therein can be replaced with equivalents without departing from the scope of the present application. In particular, as long as there is no structural conflict, the various technical features mentioned in the embodiments can be combined in any manner. The present application is not limited to the specific embodiments disclosed herein but includes some embodiments falling within the scope of the claims.

What is claimed is:

1. A light-emitting device, comprising:
a first carrier layer, wherein the first carrier layer is configured to transport holes;
a second carrier layer, wherein the second carrier layer is configured to transport electrons;
a light-emitting layer, wherein the light-emitting layer is disposed between the first carrier layer and the second carrier layer, and the light-emitting layer comprises a first sub-light-emitting layer and a second sub-light-emitting layer stacked in a direction from the first carrier layer to the second carrier layer, wherein an excited state energy level of the first sub-light-emitting layer is greater than an excited state energy level of the second sub-light-emitting layer, and a HOMO energy level of the first sub-light-emitting layer is greater than a HOMO energy level of the second sub-light-emitting layer.

2. The light-emitting device according to claim 1, wherein an electron mobility within the light-emitting layer is greater than a hole mobility within the light-emitting layer.

3. The light-emitting device according to claim 1, wherein a material of the first sub-light-emitting layer comprises a first host material and a light-emitting material, and a material of the second sub-light-emitting layer comprises a second host material and the light-emitting material, wherein a HOMO energy level of the first host material is greater than a HOMO energy level of the second host material.

4. The light-emitting device according to claim 3, wherein the HOMO energy level H1 of the first host material and the HOMO energy level H2 of the second host material satisfy: 0.1 eV≤H1−H2≤0.6 eV;
or, in the first sub-light-emitting layer, a mass ratio of the light-emitting material to the first host material is ranged from 1% to 4%.

5. The light-emitting device according to claim 3, wherein an excited state energy level of the first host material is greater than an excited state energy level of the second host material;
or, a triplet excited state energy level ET1 of the first host material is greater than a triplet excited state energy level ET2 of the second host material;
or, a triplet excited state energy level ET1 of the first host material and a triplet excited state energy level ET2 of the second host material satisfy: 0.1 eV≤ET1−ET2≤0.6 eV;
or, in the second sub-light-emitting layer, a mass ratio of the light-emitting material to the second host material is ranged from 1% to 4%.

6. The light-emitting device according to claim 3, wherein a triplet excited state energy level ET of the light-emitting material is greater than a triplet excited state energy level ET2 of the second host material;
or, a triplet excited state energy level ET of the light-emitting material and a triplet excited state energy level ET2 of the second host material satisfy: 0.1 eV≤ET−ET2≤0.6 eV.

7. The light-emitting device according to claim 3, wherein a singlet excited state energy level ES2 of the second host material is greater than a singlet excited state energy level ES of the light-emitting material;
or, a singlet excited state energy level ES2 of the second host material and a singlet excited state energy level ES of the light-emitting material satisfy: 0.1 eV≤ES2−ES≤0.6 eV.

8. The light-emitting device according to claim 1, wherein a LUMO energy level of the first sub-light-emitting layer is lower than a LUMO energy level of the second sub-light-emitting layer.

9. The light-emitting device according to claim 1, wherein a material of the first sub-light-emitting layer comprises a first host material and a light-emitting material, a material of the second sub-light-emitting layer comprises a second host material and the light-emitting material, wherein,
a LUMO energy level of the first host material is lower than a LUMO energy level of the second host material;
or, a LUMO energy level L1 of the first host material and a LUMO energy level L2 of the second host material satisfy: 0.1 eV≤L2−L1≤0.6 eV.

10. The light-emitting device according to claim 1, wherein a thickness of the first sub-light-emitting layer is less than a thickness of the second sub-light-emitting layer.

11. The light-emitting device according to claim 1, wherein the first carrier layer comprises a hole transport layer and an electron blocking layer, and the electron blocking layer is located between the hole transport layer and the first sub-light-emitting layer;
the second carrier layer comprises a hole blocking layer and an electron transport layer, and the hole blocking layer is located between the second sub-light-emitting layer and the electron transport layer,
a thickness of the hole transport layer is greater than a thickness of the electron transport layer.

12. A light-emitting device, comprising:
a first carrier layer, wherein the first carrier layer is configured to transport holes;
a second carrier layer, wherein the second carrier layer is configured to transport electrons;
a light-emitting layer, wherein the light-emitting layer is disposed between the first carrier layer and the second carrier layer, and the light-emitting layer comprises a first sub-light-emitting layer and a second sub-light-emitting layer stacked in a direction from the first carrier layer to the second carrier layer, wherein an excited state energy level of the first sub-light-emitting layer is greater than an excited state energy level of the second sub-light-emitting layer, and a LUMO energy level of the first sub-light-emitting layer is lower than a LUMO energy level of the second sub-light-emitting layer.

13. The light-emitting device according to claim 12, wherein a material of the first sub-light-emitting layer comprises a first host material and a light-emitting material, and a material of the second sub-light-emitting layer comprises a second host material and the light-emitting material, wherein:
a LUMO energy level of the first host material is lower than a LUMO energy level of the second host material;
or, a LUMO energy level L1 of the first host material and a LUMO energy level L2 of the second host material satisfy: 0.1 eV≤L2−L1≤0.6 eV;
or, a excited state energy level of the first host material is greater than a excited state energy level of the second host material;
or, a triplet excited state energy level ET1 of the first host material is greater than a triplet excited state energy level ET2 of the second host material;
or, a triplet excited state energy level ET1 of the first host material and a triplet excited state energy level ET2 of the second host material satisfy: 0.1 eV≤ET1−ET2≤0.6 eV;
or, a triplet excited state energy level ET of the light-emitting material is greater than a triplet excited state energy level ET2 of the second host material;
or, a triplet excited state energy level ET of the light-emitting material and a triplet excited state energy level ET2 of the second host material satisfy: 0.1 eV≤ET−ET2≤0.6 eV;
or, a singlet excited state energy level ES2 of the second host material is greater than a singlet excited state energy level ES of the light-emitting material;
or, a singlet excited state energy level ES2 of the second host material and a singlet excited state energy level ES of the light-emitting material satisfy: 0.1 eV≤ES2−ES≤0.6 eV.

14. The light-emitting device according to claim 12, wherein an electron mobility within the light-emitting layer is greater than a hole mobility within the light-emitting layer.

15. A light-emitting device, comprising:
a first carrier layer, wherein the first carrier layer is configured to transport holes;
a second carrier layer, wherein the second carrier layer is configured to transport electrons;
a light-emitting layer, wherein the light-emitting layer is disposed between the first carrier layer and the second carrier layer, and the light-emitting layer comprises a first sub-light-emitting layer and a second sub-light-emitting layer stacked in a direction from the first carrier layer to the second carrier layer, wherein an excited state energy level of the first sub-light-emitting layer is lower than an excited state energy level of the second sub-light-emitting layer, and a HOMO energy level of the first sub-light-emitting layer is lower than a HOMO energy level of the second sub-light-emitting layer.

16. The light-emitting device according to claim 15, wherein an electron mobility within the light-emitting layer is less than a hole mobility within the light-emitting layer.

17. The light-emitting device according to claim 15, wherein a material of the first sub-light-emitting layer comprises a first host material and a light-emitting material, and a material of the second sub-light-emitting layer comprises a second host material and the light-emitting material.

18. The light-emitting device according to claim 17, wherein,
a HOMO energy level of the first host material is lower than a HOMO energy level of the second host material;
or, a HOMO energy level H1 of the first host material and a HOMO energy level H2 of the second host material satisfy: 0.1 eV≤H2−H1≤0.6 eV;
or, a excited state energy level of the first host material is lower than a excited state energy level of the second host material.

19. The light-emitting device according to claim 17, wherein,
a triplet excited state energy level ET1 of a first host material is lower than a triplet excited state energy level ET2 of the second host material;
or, a triplet excited state energy level ET1 of a first host material and the triplet excited state energy level ET2 of the second host material satisfy: 0.1 eV≤ET2−ET1≤0.6 eV;
or, a triplet excited state energy level ET of the light-emitting material is lower than a triplet excited state energy level ET2 of the second host material;
or, a triplet excited state energy level ET of the light-emitting material and a triplet excited state energy level ET2 of the second host material satisfy: 0.1 eV≤ET2−ET≤0.6 eV;
or, a singlet excited state energy level ES2 of the second host material is lower than a singlet excited state energy level ES of the light-emitting material;
or, a singlet excited state energy level ES2 of the second host material and the singlet excited state energy level ES of the light-emitting material satisfy: 0.1 eV≤ES−ES2≤0.6 eV;
or, a LUMO energy level of the first sub-light-emitting layer is higher than a LUMO energy level of the second sub-light-emitting layer;
or, a LUMO energy level of the first host material is higher than a LUMO energy level of a second host material;
or, a LUMO energy level L1 of the first host material and a LUMO energy level L2 of the second host material satisfy: 0.1 eV≤L1−L2≤0.6 Ev.
